(19) United States
(12) Patent Application Publication
(10) Pub. No.: US 2016/0276558 A1
(43) Pub. Date: Sep. 22, 2016

(54) LIGHT EMITTING DIODE HAVING MULTILAYER BONDING PAD

(71) Applicant: ILJIN LED CO., LTD., Ansan-si (KR)

(72) Inventors: Pil Geun KANG, Ansan-si (KR); Ho Sub LEE, Ansan-si (KR); Seong Joo HWANG, Ansan-si (KR)

(21) Appl. No.: 14/412,794

(22) PCT Filed: Dec. 16, 2014
(86) PCT No.: PCT/KR2014/011979

§ 371 Date: Jan. 5, 2015

(30) Foreign Application Priority Data
Dec. 6, 2013 (KR) 10-2013-0151901

(51) Int. Cl. H01L 33/62; H01L 33/06; H01L 33/46

(52) U.S. Cl. CPC H01L 33/62; H01L 33/46; H01L 33/06; H01L 2933/0066

(57) ABSTRACT

A light-emitting diode having a multilayer bonding pad includes: a P1 layer disposed under a light-emitting structure and configured to improve ohmic contact and adhesion; a P3 layer disposed under the P1 layer and configured to prevent diffusion; a Sn-based metal layer disposed under the P1 layer and configured to enhance soldering weldability and prevent oxidation; a Cu-based P5 layer disposed on the Sn-based metal layer and configured to prevent the diffusion of Sn; and a P4 layer disposed between the P3 layer and the P5 layer and configured to suppress the reaction between the P5 layer and other layers.

### TECHNICAL FIELD

The present invention relates to a light-emitting diode, and more particularly, to a light-emitting diode having a multilayer bonding pad, which is easily mounted on a submount and a package by any selected bonding process.

### BACKGROUND ART

A light-emitting diode (LED) is a device that converts electrical energy to light. Generally, in the light-emitting diode, light is produced in at least one active layer between layers doped with impurities having opposite polarities. Specifically, when a bias is applied to both sides of the active layer, holes and electrons are injected into the active layer and recombined to produce light. A flip-type light-emitting diode is assembled by reversing the diode and bonding the n-type and p-type metal bonding pads together with a bonding layer to electrode pads, formed on a submount, by reflow soldering. In a conventional bonding process, the diode can be mounted on a submount and a package by a soldering or eutectic bonding process.

Meanwhile, Korean Patent Laid-Open Publication No. 2011-0039639 discloses a method of bonding to a submount by a soldering process that prevents overflow, and Japanese Patent Laid-Open Publication No. 2009-267069 discloses an assembly process that uses eutectic bonding. However, in order to mount a flip-type light-emitting diode, soldering or eutectic bonding needs to be freely selected according to the characteristics of a system and a process. For this reason, a bonding layer that can be bonded by either of both soldering and eutectic bonding is required. In addition, in the case of soldering, problems associated with the diffusion of Sn may arise, and poor contact may occur because an intermetallic compound layer is not formed due to the absence of UBM (under bump metal).

### DISCLOSURE

### Technical Problem

It is an object of the present invention to a light-emitting diode having a multilayer bonding pad that is easily bonded by any one selected from among soldering and eutectic bonding.

### Technical Solution

In an embodiment, a light-emitting diode having a multilayer bonding pad is a light-emitting diode including a light-emitting structure and a bonding pad, wherein the bonding pad includes: a P1 layer disposed under the light-emitting structure and configured to improve ohmic contact and adhesion; a P3 layer disposed under the P1 layer and configured to prevent diffusion; and a Sn-based metal layer configured to enhance soldering weldability and prevent oxidation. In addition, the bonding pad further includes: a Cu-based P5 layer disposed on the Sn-based metal layer and configured to prevent diffusion; and a P4 layer disposed between the P3 layer and the P5 layer and configured to suppress the reaction between the P5 layer and other layers.

Herein, the Sn-based metal layer is based on Sn and may include at least one selected from among Ti, Ni, Cr, Co, Fe, Hf, Pd, Zr, Pt, Y, Au, Ag, Cu, Ru, and compounds, mixtures and oxides thereof.

In another embodiment, a light-emitting diode having a multilayer bonding pad is a light-emitting diode including a light-emitting structure and a bonding pad, wherein the bonding pad includes: a P1 layer disposed under the light-emitting structure and configured to improve ohmic contact and adhesion; a P3 layer disposed under the P1 layer and configured to prevent diffusion; and an AuSn-based metal layer disposed under the P1 layer and configured to prevent eutectic oxidation. In addition, the bonding pad further includes: a Cu-based P5 layer disposed on the AuSn-based metal layer and configured to prevent the diffusion of Sn; a P6 layer disposed between the AuSn-based metal layer and the P5 layer and configured to suppress the reaction between the P5 layer and other layers; and a P4 layer disposed between the P3 layer and the P5 layer and configured to suppress the reaction between the P5 layer and other layers.

Herein, the AuSn-based metal layer is based on Au and Sn and may include at least one selected from among Ti, Ni, Cr, Co, Fe, Hf, Pd, Zr, Pt, Y, Au, Ag, Cu, Ru, and compounds, mixtures and oxides thereof.

In the present invention, the bonding pad may further include, between the P1 layer and the P3 layer, a P2 layer configured to reflect light emitted from the light-emitting structure, the P2 layer being made of at least one selected from among Ag, Al, Pt, Ru, Rh, Pd, and compounds, mixtures, oxides and nitrides thereof. Preferably, the P1 layer is a Cr-based metal layer, the P3 layer is a Ni-containing metal layer, the P4 layer is a Ti-containing metal layer, and the P5 layer is a Cu-containing metal layer.

In the present invention, the P6 layer may be made of at least one selected from among Ti, Ni, Cr, Co, Fe, Hf, Pd, Zr, Pt, Y, and compounds, mixtures and oxides thereof, and may function as a reaction-preventing layer that prevents the penetration of Sn. Preferably, the P6 layer is a Ti-containing metal layer. The P1 layer may be made of at least one selected from among ITO, Ni, Cr, Ti, Hf, Rh, W, Zr, V, Cu, Co, Fe, In, Sn, Zn, Pd, and compounds, mixtures, oxides and nitrides thereof. The P3 layer may be made of at least one selected from among Ni, Mo, Co, La, Ta, Ti, W, Pt, Hf, Y, and compounds, mixtures and oxides thereof. The P4 layer may be made of at least one selected from among Ti, Ni, Cr, Co, Fe, Hf, Pd, Zr, Pt, V, Y, and compounds, mixtures and oxides thereof. The P5 layer may be made of at least one selected from among Cu, W, Mo, Ti, Ta, Zr, C, and compounds, mixtures and carbides thereof.

The bonding pad according to the present invention may further include an insulating film that insulates the bonding pad, and the insulating film may include a DBR layer made of at least one selected from among compounds, mixtures, oxides and nitrides, which contain Si, Ti, Mg, Al, Zn, In, Sn or C. The DBR layer may be made at least one selected from among fluorides, sulfides and nitrides, which contain Si, Ti, Mg, Al, Zn, In, Sn or C.

In a preferred embodiment, the bonding pad may further include an insulating film that insulates the bonding pad, and the insulating film may be composed of a sequential stack of: a first ODR layer made of at least one selected from compounds, mixtures, oxides and nitrides, which contain Si, Ti, Mg, Al, Zn, In, Sn or C; a second ODR layer made of at least one selected from among Ag, Al, Pt, Ru, Rh, Pd, and compounds, mixtures, oxides and nitrides thereof; and a third ODR layer made of at least one selected from among compounds, mixtures, oxides and nitrides, which contain Si, Ti, Mg, Al, Zn, In, Sn or C.

The insulating film of the bonding pad according to the present invention may further include a fourth ODR layer disposed on the third ODR layer and made of at least one selected from among Ti, Ni, Cr, Co, Fe, Hf, Pd, Zr, Pt, Y, and compounds, mixtures, oxides and nitrides thereof. The first ODR layer may be made of any one selected from oxides, fluorides, sulfides and nitrides, which contain Si, Ti, Mg, Al, Zn, In, Sn or C. The first ODR layer may be made of any one selected from among oxides and fluorides, which contain Si, Ti, Mg, Al, Zn, In, Sn or C.

### Advantageous Effects

A light-emitting diode having a multilayer bonding pad according to the present invention has a multilayer bonding pad capable of being bonded by any one selected from soldering and eutectic bonding, and thus may be mounted by any one selected from soldering and eutectic bonding. Further, it includes a layer containing components capable of forming an intermetallic compound, and thus can simultaneously overcome poor contact that can occur during soldering, and the problems associated with the diffusion of a solder component. In addition, a layer for preventing the diffusion of a material during eutectic bonding is added to the bonding pad layers, and thus the diffusion of the material can be prevented.

### DESCRIPTION OF DRAWINGS

FIG. 1 is a cross-sectional view showing a light-emitting diode having a multilayer bonding pad according to the present invention.

FIG. 2 is a cross-sectional view showing a DBR layer that is an insulating film according to the present invention.

FIG. 3 is a cross-sectional view showing an ODR layer that is an insulating film according to the present invention. FIG. 4 is a cross-sectional view showing a bonding pad according to the present invention.

### DESCRIPTION OF REFERENCE NUMERALS USED IN THE DRAWINGS

10: substrate; 12: first semiconductor layer;
14: active layer; 15: light-emitting structure;
16: second semiconductor layer; 18: reflective layer;
20: insulating film; 22: bonding layer; 24: submount;
Pa and Pb: first and second bonding pads.

### MODE FOR INVENTION

Hereinafter, preferred embodiments of the present invention will be described with reference to the accompanying drawings. The embodiments set forth herein can be modified in various other forms, and the scope of the present invention is not limited to these embodiments. The embodiments of the present invention are provided in order to more completely explain the present invention to those skilled in the art.

Embodiments of the present invention provide a light-emitting diode that has a multilayer bonding pad capable of being bonded by any one selected from soldering or eutectic bonding. Thus, the light-emitting diode may be mounted by any one selected from among soldering or eutectic bonding, and can overcome the problems of soldering. For this, a composition forming the multilayer bonding pad will be described in detail. The multilayer bonding pad according to the present invention is preferably applied to a flip-type light-emitting diode.

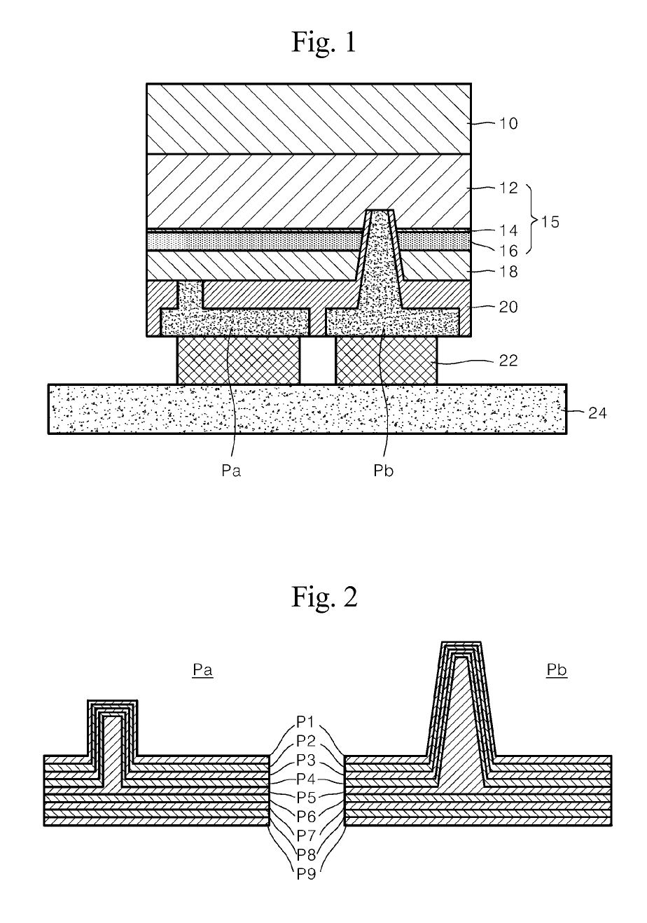

FIG. 1 is a cross-sectional view showing a light-emitting diode having a multilayer bonding pad according to an embodiment of the present invention.

Referring to FIG. 1, the light-emitting diode of the present invention includes a substrate 10 and a light-emitting structure 15 including: a first semiconductor layer 12, an active layer 14 and a second semiconductor layer 16, which are placed over one side of the substrate 10. On the light-emitting structure 15, a reflective layer 18, an insulating film 20, first and second bonding pads Pa and Pb, and a bonding layer 22 are sequentially formed. Herein, the first and second bonding pads Pa and Pb are filled in contact holes formed in the insulating film 20, and are electrically connected to the reflective layer 18 and the first semiconductor layer 12, respectively. The bonding layer 22 is bonded to an electrode pad (not shown) disposed on a submount 24 (a printed circuit board or a lead frame).

The substrate 10 may be made of any one of sapphire (Al₂O₃), silicon carbide (SiC), gallium nitride (GaN), gallium arsenide (GaAs), silicon (Si), germanium (Ge), zinc oxide (ZnO), magnesium oxide (MgO), aluminum nitride (AlN), boron nitride (BN), gallium phosphide (GaP), indium phosphide (InP), and lithium aluminum oxide (LiAl₂O₃). A plurality of conductivity-type semiconductor layers in the light-emitting structure 15 may have any one of an np junction structure, a pn junction structure, an npn junction structure, and a pnp junction structure, with respect to the substrate 10. For example, when the light-emitting structure is an np junction structure, the first semiconductor layer 12 is an n-type semiconductor layer, and the second semiconductor layer 16 is a p-type semiconductor layer.

The first and second semiconductor layers 12 and 16 may include different impurities so as to have different conductivity types. For example, the first semiconductor layer 12 may include n-type impurities, and the second semiconductor layer 16 may include p-type impurities. When the light-emitting structure 15 is an np junction structure, the first semiconductor layer 12 may include n-type impurity doped n-type AlxInyGazN (0≦x, y, z≦1, x+y+z=1), n-type GaN or the like. Herein, the n-type impurity may be at least one selected from among silicon (Si), germanium (Ge), tin (Sn), selenium (Se) and tellurium (Te). The second semiconductor layer 16 may be made of p-type impurity-doped p-type AlxInyGazN (0≦x, y, z≦1, x+y+z=1), p-type GaN or the like. The p-type impurity may be at least one selected from among magnesium (Mg), zinc (Zn), calcium (Ca), strontium (Sr), beryllium (Be) and barium (Ba).

The active layer 14 has an energy band gap lower than those of the first and second semiconductor layers 12 and 16, and thus can activate luminescence. The active layer 14 can emit light at various wavelengths. For example, it can emit infrared light, visible light or ultraviolet light. The active layer 14 may include a compound composed of elements of Groups III to V. For example, it may include AlxInyGazN (0≦x, y, z≦1, x+y+z=1), InGaN or AlGaN. In addition, the active layer 14 may be a single quantum well (SQW) or a multi quantum well (MQW). Further, the active layer 14 may be composed of a stack of quantum well layers and quantum barrier layers, and the number of the quantum well layers and the quantum barrier layers can be properly selected according to necessity. Also, the active layer 14 may have, for example, a GaN/InGaN/GaN MQW structure or a GaN/AlGaN/GaN MQW structure. However, this is illustrative only, and the wavelength of light emitted from the active layer 14 changes depending on the components of the active layer 14.

The reflective layer 18 is made of a metal having high light reflectivity, and may be composed of up to 10 layers. A first reflective layer functions to form an ohmic contact with the second semiconductor layer 16 and attach a second reflective layer to the second semiconductor layer 16. The first reflective layer may be made of at least one selected from among Al, C, ITO, Ni, Cr, Cu, Co, Fe, Hf, In, La, Sn, Ti, Zn, Pd, Zr, Pt, Y, and compounds, mixtures and oxides thereof. The thickness of the first reflective layer may be 1-2,000 Å, and is preferably 100 Å or less. Herein, “Å” is angstrom. The second reflective layer functions to reflect the light generated in the light-emitting structure 15. The second reflective layer may be made of at least material selected from among Ag, Al, Pt, Ru, Rh, Pd, and compounds, mixtures and oxides thereof. The thickness of the second reflective layer may be 1,000-10,000 Å, and is preferably 1,000-5,000 Å.

A third reflective layer functions to prevent the second reflective layer from reacting with other materials to reduce the reflectivity. The third reflective layer may be made of at least one selected from among Ni, Mo, Co, La, Ta, Ti, W, Pt, Hf, Zr, and compounds, mixtures and oxides thereof. The thickness of the third reflective layer may be 50-10,000 Å, and is preferably 200-3,000 Å. A fourth reflective layer functions to protect the third reflective layer, and may be omitted in some cases. The fourth reflective layer may be made of at least one material selected from among Au, Pt, Pd, Rh, Ru, and compounds, mixtures and oxides thereof. The thickness of the fourth reflective layer is preferably 100-10,000 Å, and more preferably 100-2,000 Å.

A fifth reflective layer functions to securely attach the fourth reflective layer to a sixth reflective layer, add may be omitted in some cases. The fifth reflective layer may be made of at least one selected from among Ti, Ni, Co, Rh, Cr, V, W, and compounds, mixtures and oxides thereof. The thickness of the fifth reflective layer is preferably 50-10,000 Å, and more preferably 100-1,000 Å. A sixth reflective layer functions to prevent the second to fourth reflective layers from reacting with other materials to reduce reflectivity, and may be omitted in some cases. The sixth reflective layer may be made of at least one material selected from among Ni, Mo, Co, La, Ta, Ti, W, Pt, Hf, V, Zr, and compounds, mixtures and oxides thereof. The thickness of the sixth reflective layer is preferably 50-10,000 Å, and more preferably 200-5,000 Å. A seventh reflective layer functions to prevent the sixth reflective layer from reacting with other materials to increase the operating voltage. The seventh reflective layer may be made of at least one selected from among Ni, Mo, Co, La, Ta, Ti, W, Pt, Hf, Zr, and compounds, mixtures and oxides thereof. The thickness of the seventh reflective layer is preferably 50-10,000 Å, and more preferably 200-3,000 Å.

An eighth reflective layer functions to facilitate the adhesion of the seventh layer to the insulating film 20 when ninth and tenth reflective layers as described below are not present. If the ninth and tenth reflective layers are present, the eighth reflective layer functions to prevent the seventh reflective layer from reacting with the ninth reflective layer. The eighth reflective layer may be made of at least one selected from among Ti, Ni, Cr, Co, Fe, Hf, Pd, Zr, Pt, Y, and compounds, mixtures and oxides thereof. The thickness of the eighth reflective layer may be 1-2,000 Å, and is preferably 500 Å or less. The ninth reflective layer functions as a wiring through which an applied electric current can smoothly flow, and may be omitted in some cases. The ninth reflective layer may be made of at least one material selected from among compounds, mixtures and carbides, which contain Cu, W, Mo, Ti, Ta, Zr or C. The thickness of the ninth reflective layer is preferably 1,000-50,000 Å, and more preferably 8,000-20,000 Å. The tenth reflective layer functions to prevent the ninth reflective layer from reacting with other materials to increase the operating voltage. If the ninth reflective layer is omitted, the tenth reflective layer may also be omitted. The tenth reflective layer may be at least one selected from among Ti, Ni, Mo, Co, Ta, W, Pt, Hf, Zr, La, and compounds, mixtures and oxides thereof. The thickness of the tenth reflective layer is preferably 50-10,000 Å, and more preferably 200-3,000 Å.

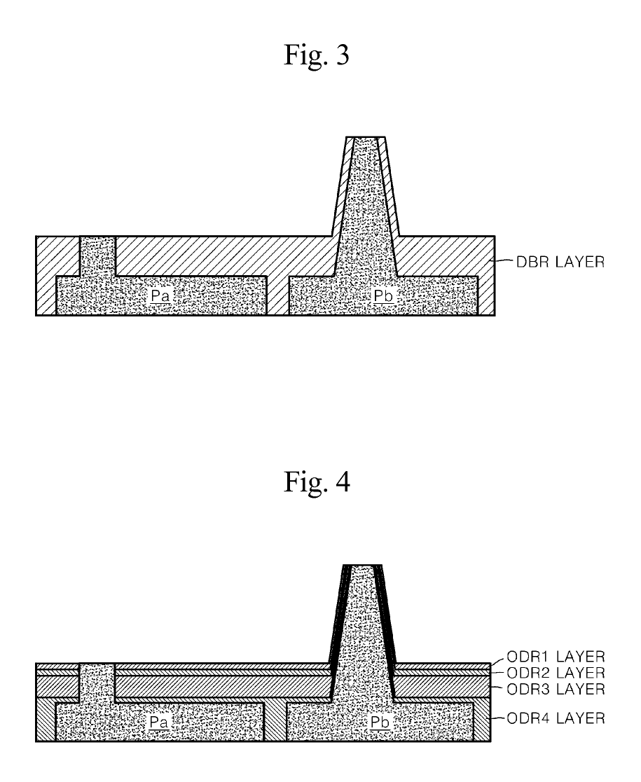

FIG. 2 is a cross-sectional view showing a DBR layer that is an insulating film according to an embodiment of the present invention. FIG. 3 is a cross-sectional view showing an ODR layer that is an insulating film according to an embodiment of the present invention.

Referring to FIGS. 2 and 3, the insulating film 20 functions to electrically insulate a positive electrode and a negative electrode from each other. The insulating film 20 may be made of at least one selected from among compounds and mixtures, which contain Si, Mg, Ti, Al, Zn, C, In or Sn, or may be made of at least one selected from oxides, fluorides, sulfides and nitrides of these elements. In addition, it may have a multilayer structure and may be used as any one of a DBR (Distributed Bragg Reflector) layer or an ODR (Omni Directional Reflector) layer. If it is used as the DBR layer, it is composed of a plurality of layers having different reflective indices. The DBR layer may be made of any one selected from compounds, mixtures, oxides and nitrides, which contain Si, Ti, Ta, V, Cr, Mg, Al, Zn, In, Sn or C, or may be made of any one selected from among fluorides, sulfides and nitrides of these elements. Among them, any one of the oxides, nitrides and fluorides is more preferably used. The thickness of the DBR layer is preferably 10-900 Å, and the number of deposition cycles of the DBR layer is not limited, but is preferably 20 cycles (k=20) or less.

If the insulating film 20 is used as an ODR layer, it is preferably composed of 4 layers. A first ODR layer may be composed of a dielectric thin film having a low reflective index. The first ODR layer may be made of at least one selected from among compounds, mixtures, oxides and nitrides, which contain Si, Ti, Mg, Al, Zn, In, Sn or C, or may be may be made of any one selected from among fluorides, sulfides and nitrides of these elements. Among them, oxides or fluorides are preferable. The thickness of the first ODR layer may be 10-5,000 Å, and is preferably 10-1,000 Å. A second ODR layer functions to reflect the emitted light, like the reflective layer 18. The second ODR material may be made of at least one material selected from among Ag, Al, Pt, Ru, Rh, Pd, and compounds, mixtures, oxides and nitrides thereof. The thickness of the second ODR layer is preferably 1,000-10,000 Å, and more preferably 1,000-5,000 Å.

A third ODR layer functions to prevent the oxidation of the second ODR layer and electrically insulate the second ODR layer. The third ODR layer may be made of at least one selected from among compounds, mixtures, oxides and nitrides, which contain Si, Ti, Mg, Al, Zn, In, Sn or C, or may be made of any one selected from fluorides, sulfides and nitrides of these elements. Among them, any one of oxides, nitrides and fluorides is more preferable. The thickness of the third ODR layer is preferably 100-20,000 Å, and more preferably 1,000-20,000 Å. A fourth ODR layer functions to attach the ODR layer to the first and second bonding pads Pₐ and P_{b}, and may be omitted in some cases. The fourth ODR layer may be made of at least one material selected from among Ti, Ni, Cr, Co, Fe, Hf, Pd, Zr, Pt, Y, and compounds, mixtures, oxides and nitrides thereof. The thickness of the fourth ODR layer is preferably 1-2,000 Å, and more preferably 500 Å or less.

FIG. 4 is a cross-sectional view showing a bonding pad according to an embodiment of the present invention.

Referring to FIG. 4, the first and second bonding pads Pa and Pb form the positive electrode and negative electrode of the light-emitting diode, and may be eutectically bonded or soldered. Each of the bonding pads is preferably composed of up to 9 layers. A P1 layer forms an ohmic contact with the first semiconductor layer 14 and functions as an adhesive in the bonding pads Pa and Pb. The P1 layer may be made of at least one selected from among ITO, Ni, Cr, Ti, Hf, Rh, W, Zr, V, Cu, Co, Fe, In, Sn, Zn, Pd, and compounds, mixtures, oxides and nitrides thereof. Preferably, the P1 layer is made of Cr. The thickness of the P1 layer is preferably 1-2,000 Å, and more preferably 5-1,000 Å. A P2 layer functions to reflect emitted light, and may be omitted in some cases. The P2 layer may be made of at least one material selected from among Ag, Al, Pt, Ru, Rh, Pd, and compounds, mixtures, oxides and nitrides thereof. Preferably, the P2 layer is made of Al. The thickness of the P2 layer is preferably 1,000-10,000 Å, and more preferably 1,000-3,000 Å.

A P3 layer functions as a barrier layer that prevents diffusion between the P1 layer and a P4 layer or between the P2 layer and the P4 layer. The P3 layer may be made of at least one selected from among Ni, Mo, Co, La, Ta, Ti, V, W, Pt, Hf, Y, and compounds, mixtures and oxides thereof. Preferably, the P3 layer is made of Ni. To enhance the diffusion-preventing function of the P3 layer, the P3 layer may be composed of a plurality of material layers. Herein, the number of the layers may be 1 to n (n=natural number). The thickness of the P3 layer is preferably 100-10,000 Å, and more preferably 500-3,000 Å. A P4 layer enables the P3 layer and a P5 layer to easily adhere to each other, and functions as a reaction-preventing layer that, for example, prevents the diffusion of Sn. The P4 layer may be made of at least one selected from among Ti, Ni, Cr, Co, Fe, Hf, Pd, Zr, Pt, Y, and compounds, mixtures and oxides thereof. Preferably, the P4 layer is made of Ti. The thickness of the P4 layer may be 1-2,000 Å, and is preferably 1,000 Å or less.

A P5 layer functions as UBM (under mump metal) during soldering, and may also function to prevent the diffusion of Sn and as a wiring layer. Particularly, it forms an intermetallic compound from a Cu- or Sn-based compound. The P5 layer may be made of at least one selected from among compounds, mixtures and carbides, which contain Cu, W, Mo, Ti, Ta, Zr or C. Preferably, the P5 layer is made of Cu. The thickness of the P5 layer may be 2,000-50,000 Å, and is preferably 5,000-20,000 Å. A P6 layer enables the P5 layer and a P7 layer to easily adhere to each other, and functions to prevent the P5 layer from reacting with other layers. The P6 layer may be made of at least one material selected from among Ti, Ni, Cr, Co, Fe, Hf, Pd, Zr, Pt, Y, and compounds, mixtures and oxides thereof. Preferably, the P6 layer is preferably made of Ti. The thickness of the P6 layer may be 1-2,000 Å, and is preferably 1,000 Å or less.

A P7 layer enables an intermetallic compound to be formed during soldering, and functions as a barrier layer that prevents the diffusion of Sn. The P7 layer may be at least one selected from among Ni, Mo, Co, La, Ta, Ti, W, Pt, Hf, Y, and compounds, mixtures and oxides thereof. Preferably, the P7 layer is made of Ni. To enhance the diffusion-preventing function of the P7 layer, the P7 layer may be composed of a plurality of layers. Herein, the number of the layers may be 1 to n (n=natural number). The thickness of the P7 layer may be 100-10,000 Å, and is preferably 500-3,000 Å. The P4, P5, P6 and P7 layers play a great role in solving the problems associated with the diffusion of Sn and the soldering problem in that an intermetallic compound layer is not formed due to the absence of UBM (under bump metal).

A P8 layer enables either eutectic bonding or soldering. Particularly, it improves adhesion when soldering is performed, and functions as an adhesive layer when eutectic bonding is performed. The P8 layer may be at least one material selected from among Au, Ni, Ag, Cu, Pd, Pt, Sn, and compounds and mixtures thereof. Preferably, the P8 layer is made of an AuSn alloy. The thickness of the P8 layer may be 1,000-100,000 Å, and is preferably 20,000-50,000 Å. The P8 layer enables the soldering or eutectic bonding of the first and second bonding pads Pₐ and P_{b} of the present invention. A P9 layer functions to prevent the eutectic oxidation of the P6 layer during eutectic bonding, and allows the P6 layer to be wet with a solder during soldering. The P9 layer may be made of at least one selected from Au, Pd, Pt, Ru, Ag, and compounds and mixtures thereof. As used herein, the term “eutectic oxidation” refers to oxidation of the bonding pad during eutectic bonding. Preferably, the P9 is made of Au. The thickness of the P9 layer may be 10-10,000 Å, and is preferably 50-10,000 Å.

The bonding layer 22 serves as a bump for soldering or eutectic bonding. For soldering, the bonding layer 22 may be formed of an alloy of at least two selected from among Cr, Ti, Pt, Au, Mo and Sn, for example, Au/Sn, Pt/Au/Sn, Cr/Au/Sn or the like. Preferably, it is formed of a Sn alloy. For eutectic bonding, the bonding layer 22 may be made of an alloy based on Sn, Ag, Cu or the like. Preferably, it is preferably formed of an AuSn alloy, a NiSn alloy, or an AgSn alloy. Through the bonding layer 22, the light-emitting diode having the first and second bonding pads Pₐ and P_{b} according to the present invention is mounted on a submount 24. Because the first and second bonding pads Pₐ and P_{b} according to the present invention can be bonded by any one of soldering and eutectic bonding processes, a user can mount the light-emitting diode using any one selected from among the two processes.

Hereinafter, the first and second bonding pads Pₐ and P_{b} will be described with reference to a product obtained after completion of a soldering or eutectic bonding process. First, a product obtained after completion of a soldering process includes: a P1 layer provided under the light-emitting structure and functioning to form an ohmic contact and increase adhesion; a P3 layer provided under the P1 layer and functioning to prevent diffusion; a Sn-based metal layer functioning to enhance soldering wettability and prevent oxidation; a Cu-based P5 layer formed on the Sn-based metal layer and functioning to prevent the diffusion of Sn; and a P4 layer formed between the P3 layer and the P5 layer and functioning to suppress the reaction between the P5 layer and other layers. Herein, the Sn-based metal layer is based on Sn, and may include at least one selected from among Ti, Ni, Cr, Co, Fe, Hf, Pd, Zr, Pt, Y, Au, Ag, Cu, Ru, and compounds, mixtures and oxides thereof.

In addition, in a product obtained after completion of an eutectic bonding process, the first and second bonding pads Pₐ and P_{b} include: a P1 layer provided under the light-emitting structure and functioning to form an ohmic contact and increase adhesion; a P3 layer provided under the P1 layer and functioning to prevent diffusion; an AuSn-based metal layer functioning to prevent eutectic oxidation; a Cu-based P5 layer formed on the AuSn-based metal layer and functioning to prevent the diffusion of Sn; a P6 layer provided between the AuSn-based metal layer and the P5 layer and functioning to suppress the reaction between the P5 layer and other layers; and a P4 layer provided between the P3 layer and the P5 layer and functioning to suppress the reaction between the P5 layer and other layers. Herein, the AuSn-based metal layer is based on Au and Sn, and may include at least one selected from among Ti, Ni, Cr, Co, Fe, Hf, Pd, Zr, Pt, Y, Au, Ag, Cu, Ru, and compounds, mixtures and oxides thereof.

Although the preferred embodiments of the present invention have been disclosed for illustrative purposes, the scope of the present invention is not limited to the embodiments, and those skilled in the art will appreciate that various modifications are possible, without departing from the scope and spirit of the invention as disclosed in the accompanying claims.

1-16. (canceled)

17. A light-emitting diode comprising a light-emitting structure and a multilayer bonding pad, wherein the bonding pad comprises:
a P1 layer disposed under the light-emitting structure and configured to improve ohmic contact and adhesion;
a P3 layer disposed under the P1 layer and configured to prevent diffusion;
a Sn-based metal layer configured to enhance soldering weldability and prevent oxidation;
a Cu-based P5 layer disposed on the Sn-based metal layer and configured to prevent diffusion of Sn; and
a P4 layer disposed between the P3 layer and the P5 layer and configured to suppress a reaction between the P5 layer and other layers.

18. The light-emitting diode of claim 17, wherein the Sn-based metal layer comprises at least one selected from the group consisting of Ti, Ni, Cr, Co, Fe, Hf, Pd, Zr, Pt, Y, Au, Ag, Cu, Ru, compounds thereof, mixtures thereof and oxides thereof.

19. The light-emitting diode of claim 17, wherein the bonding pad further comprises, between the P1 layer and the P3 layer, a P2 layer configured to reflect light emitted from the light-emitting structure, the P2 layer comprises at least one selected from the group consisting of Ag, Al, Pt, Ru, Rh, Pd, compounds thereof, mixtures, oxides thereof and nitrides thereof.

20. The light-emitting diode of any one of claim 17, wherein the P1 layer is a Cr-based metal layer, the P3 layer is a Ni-containing metal layer, the P4 layer is a Ti-containing metal layer, and the P5 layer is a Cu-containing metal layer.

21. The light-emitting diode of claim 17, wherein the P1 layer comprises at least one selected from the group consisting of ITO, Ni, Cr, Ti, Hf, Rh, W, Zr, V, Cu, Co, Fe, In, Sn, Zn, Pd, compounds thereof, mixtures thereof, oxides and nitrides thereof.

22. The light-emitting diode of claim 17, wherein the P3 layer comprises at least one selected from the group consisting of Ni, Mo, Co, La, Ta, Ti, W, Pt, Hf, Y, compounds thereof, mixtures thereof and oxides thereof.

23. The light-emitting diode of claim 17, wherein the P4 layer comprises at least one selected from the group consisting of Ti, Ni, Cr, Co, Fe, Hf, Pd, Zr, Pt, V, Y, and compounds, mixtures and oxides thereof.

24. The light-emitting diode of claim 17, wherein the P5 layer comprises at least one selected from the group consisting of Cu, W, Mo, Ti, Ta, Zr, C, and compounds, mixtures and carbides thereof.

25. The light-emitting diode of claim 17, further comprising an insulating film that insulates the bonding pad, in which the insulating film comprises a DBR layer comprises at least one selected from the group consisting of compounds, mixtures, oxides and nitrides, which contain Si, Ti, Mg, Al, Zn, In, Sn or C.

26. The light-emitting diode of claim 17, further comprising an insulating film that insulates the bonding pad, in which the insulating film is composed of a sequential stack of:
a first ODR layer comprises at least one selected from the group consisting of compounds, mixtures, oxides and nitrides, which contain Si, Ti, Mg, Al, Zn, In, Sn or C;
a second ODR layer comprises at least one selected from the group consisting of Ag, Al, Pt, Ru, Rh, Pd, and compounds, mixtures, oxides and nitrides thereof; and
a third ODR layer comprises at least one selected from the group consisting of compounds, mixtures, oxides and nitrides, which contain Si, Ti, Mg, Al, Zn, In, Sn or C.

27. The light-emitting diode of claim 26, wherein the insulating film further comprises a fourth ODR layer disposed on the third ODR layer and comprises at least one selected from the group consisting of Ti, Ni, Cr, Co, Fe, Hf, Pd, Zr, Pt, Y, and compounds, mixtures, oxides and nitrides thereof.

28. The light-emitting diode of claim 17, further comprising a single-layer or multilayer reflective layer.

29. A light-emitting diode comprising a light-emitting structure and a multilayer bonding pad, wherein the bonding pad comprises:
a P1 layer disposed under the light-emitting structure and configured to improve ohmic contact and adhesion;
a P3 layer disposed under the P1 layer and configured to prevent diffusion;
an AuSn-based metal layer disposed under the P1 layer and configured to prevent eutectic oxidation;
a Cu-based P5 layer disposed on the AuSn-based metal layer and configured to prevent diffusion of Sn;
a P6 layer disposed between the AuSn-based metal layer and the P5 layer and configured to suppress a reaction between the P5 layer and other layers; and
a P4 layer disposed between the P3 layer and the P5 layer and configured to suppress the reaction between the P5 layer and other layers.

30. The light-emitting diode of claim 29, wherein the AuSn-based metal layer comprises at least one selected from the group consisting of Ti, Ni, Cr, Co, Fe, Hf, Pd, Zr, Pt, Y, Au, Ag, Cu, Ru, compounds thereof, mixtures thereof and oxides thereof.

31. The light-emitting diode of claim 29, wherein the bonding pad further comprises, between the P1 layer and the P3 layer, a P2 layer configured to reflect light emitted from the light-emitting structure, the P2 layer comprises at least one selected from the group consisting of Ag, Al, Pt, Ru, Rh, Pd, compounds thereof, mixtures, oxides thereof and nitrides thereof.

32. The light-emitting diode of claim 29, wherein the P1 layer is a Cr-based metal layer, the P3 layer is a Ni-containing metal layer, the P4 layer is a Ti-containing metal layer, and the P5 layer is a Cu-containing metal layer.

33. The light-emitting diode of claim 29, wherein the P6 layer comprises at least one selected from the group consisting of Ti, Ni, Cr, Co, Fe, Hf, Pd, Zr, Pt, Y, compounds thereof, mixtures thereof and oxides thereof, and functions as a reaction-preventing layer that prevents penetration of Sn.

34. The light-emitting diode of claim 33, wherein the P6 layer includes a Ti-containing metal layer.

35. The light-emitting diode of claim 29, wherein the P1 layer comprises at least one selected from the group consisting of ITO, Ni, Cr, Ti, Hf, Rh, W, Zr, V, Cu, Co, Fe, In, Sn, Zn, Pd, compounds thereof, mixtures thereof, oxides and nitrides thereof.

36. The light-emitting diode of claim 29, wherein the P3 layer comprises at least one selected from the group consisting of Ni, Mo, Co, La, Ta, Ti, W, Pt, Hf, Y, compounds thereof, mixtures thereof and oxides thereof.

37. The light-emitting diode of claim 29, wherein the P4 layer comprises at least one selected from the group consisting of Ti, Ni, Cr, Co, Fe, Hf, Pd, Zr, Pt, V, Y, and compounds, mixtures and oxides thereof.

38. The light-emitting diode of claim 29, wherein the P5 layer comprises at least one selected from the group consisting of Cu, W, Mo, Ti, Ta, Zr, C, and compounds, mixtures and carbides thereof.
